(19) United States
(12) Patent Application Publication
(10) Pub. No.: US 2012/0125667 A1
(43) Pub. Date: May 24, 2012

(54) PRINTED CIRCUIT BOARD AND METHOD OF MANUFACTURING THE SAME

(75) Inventors: Hyung Mi JUNG, Suwon (KR); Jae Choon Cho, Suwon (KR); Choon Keun Lee, Suwon (KR)

(73) Assignee: SAMSUNG ELECTRO-MECHANICS CO., LTD.

(21) Appl. No.: 13/159,866

(22) Filed: Jun. 14, 2011

(30) Foreign Application Priority Data
Nov. 18, 2010 (KR) 10-2010-0115289

(51) Int. Cl. H05K 1/02; H05K 3/00

(52) U.S. Cl. 174/251; 29/846

(57) ABSTRACT

There are provided a printed circuit board and a method of manufacturing the same. The printed circuit board includes a first circuit pattern formed on a core substrate; an insulating layer stacked on the core substrate to cover the first circuit pattern and having a uniform surface roughness on a nano scale; a second circuit pattern formed on the insulating layer; and a via pattern electrically connecting the first circuit pattern to the second circuit pattern and penetrating through the insulating layer.

### CROSS-REFERENCE TO RELATED APPLICATIONS

This application claims the priority of Korean Patent Application No. 10-2010-0115289 filed on Nov. 18, 2010, in the Korean Intellectual Property Office, the disclosure of which is incorporated herein by reference.

### BACKGROUND OF THE INVENTION

1. Field of the Invention

The present invention relates to a printed circuit board and a method of manufacturing the same, and more particularly, to a printed circuit board having a fine circuit pattern formed by having a uniform roughness formed on a surface of an insulating layer through a simple method and a method of manufacturing the same.

2. Description of the Related Art

Recently, in the field of electronics, a mounting technology using a high-density, high-resolution, and high-integration printed circuit board has been adopted when mounting components thereon in order to make electronic devices slim and compact. Such printed circuit boards are used in various roles, such as in factory automation (FA) equipment, in office automation (OA) equipment, in communication equipments, in broadcasting equipment, in portable computers, and the like.

In particular, the miniaturization and high-densification of printed circuit boards are also simultaneously being performed, as electronic products are becoming miniaturized, high-integrated, packaged, and lightweight and thin due to personal portability. In addition, with the development of a chip size package (CSP) technology such as a ball grid array (BGA) method, a tape carrier package (TCP) method, or the like, interest in a high-density printed circuit board on which chips may be mounted is also gradually increasing.

As a method of implementing a package printed circuit board, there are a subtractive method, a semi additive process (SAP) method, a modified semi additive process (MSAP) method, and the like.

In the subtractive method, panel plating is performed on existing copper foil in a copper clad laminate (CCL) using electrolytic copper, such that a thickness of the entire copper foil is increased.

Due to etching factors generated when etching the thick copper foil, a fine circuit may not be formed. Therefore, in order to implement the fine circuit, a desired circuit may be obtained by forming a conductive layer on an insulating material by electroless plating and electrolyte plating using the SAP method or the MSAP method and then performing an etching method thereon, or the like. However, in this case, a problem may arise in which the adhesion between the insulating material and the conductive layer should be secured.

In addition, in the case of the printed circuit board, if a circuit pattern has a fine width, greater adhesion between the insulating layer and the conductive layer is required, and as a result, fine, uniform roughness should be formed on a surface of the insulating layer in order to secure a predetermined amount of adhesion.

### SUMMARY OF THE INVENTION

An aspect of the present invention provides a printed circuit board allowing for the formation of a fine pattern by securing a uniform roughness on an insulating layer and securing adhesion between a conductive layer and the insulating layer.

Another aspect of the present invention provides a method of manufacturing a printed circuit board having a fine pattern thereon by forming a uniform roughness on an insulating layer and strengthening adhesion between a conductive layer and the insulating layer.

According to an aspect of the present invention, there is provided a printed circuit board including: a core substrate having a first circuit pattern formed thereon; and an insulating layer formed on the core substrate and having a uniform surface roughness on a nanoscale formed thereon.

The printed circuit board may further include a second circuit pattern formed on the insulating layer having the roughness formed thereon by plating.

The printed circuit board may further include a via pattern electrically connecting the first circuit pattern to the second circuit pattern and penetrating through the insulating layer.

The insulating layer may have an arithmetical average roughness (Ra) of 300 nm or less.

The arithmetical average roughness (Ra) may range from 150 to 250 nm.

The second circuit pattern may have a line/space interval of 10 μm/10 μm or less.

The second circuit pattern may have a thickness of 25 μm or less.

The insulating layer may have a thickness of 100 μm or less.

According to another aspect of the present invention, there is provided a method of manufacturing a printed circuit board, the method including: preparing a core substrate having a first circuit pattern formed thereon; forming an insulating layer on the core substrate; transferring a surface roughness of a metal foil on the insulating layer and forming a uniform surface roughness thereon; and forming a second circuit pattern and a via pattern electrically connecting the first circuit pattern to the second circuit pattern on the insulating layer.

The second circuit pattern and the via pattern may be formed by plating.

The metal foil may be copper foil.

The forming of the roughness may include: attaching the metal foil to the insulating layer; and removing the metal foil.

The removing of the metal foil may performed by full-etching or semi-etching of the metal foil.

The second circuit pattern and the via pattern may be formed by a semi additive process (SAP) method or a modified semi additive process (MSAP) method.

The insulating layer may have an arithmetical average roughness (Ra) of 300 nm or less.

The arithmetical average roughness (Ra) may range from 150 to 250 nm.

The second circuit pattern may have a line/space interval of 10 μm/10 μm or less.

The second circuit pattern may have a thickness of 25 μm or less.

The insulating layer may have a thickness of 100 μm or less.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a flowchart showing a method of manufacturing a printed circuit board according to an exemplary embodiment of the present invention;

FIGS. 2A to 2E show a process forming a circuit pattern in a semi additive process (SAP) method according to an exemplary embodiment of the present invention;

FIGS. 3A to 3C show a process forming a circuit pattern in a modified semi additive process (MSAP) method according to another exemplary embodiment of the present invention; and

FIG. 4 is a cross-sectional view showing a printed circuit board having a fine circuit pattern according to an exemplary embodiment of the present invention.

### DETAILED DESCRIPTION OF THE PREFERRED EMBODIMENT

Hereinafter, exemplary embodiments of the present invention will be described in detail with reference to the accompanying drawings so that they can be easily practiced by those skilled in the art to which the present invention pertains. However, in describing the exemplary embodiments of the present invention, detailed descriptions of well-known functions or constructions are omitted so as not to obscure the description of the present invention with unnecessary detail.

In addition, like reference numerals denote parts performing similar functions and actions throughout the drawings.

In addition, unless explicitly described to the contrary, the word “comprise” and variations such as “comprises” or “comprising,” will be understood to imply the inclusion of stated elements but not the exclusion of any other elements.

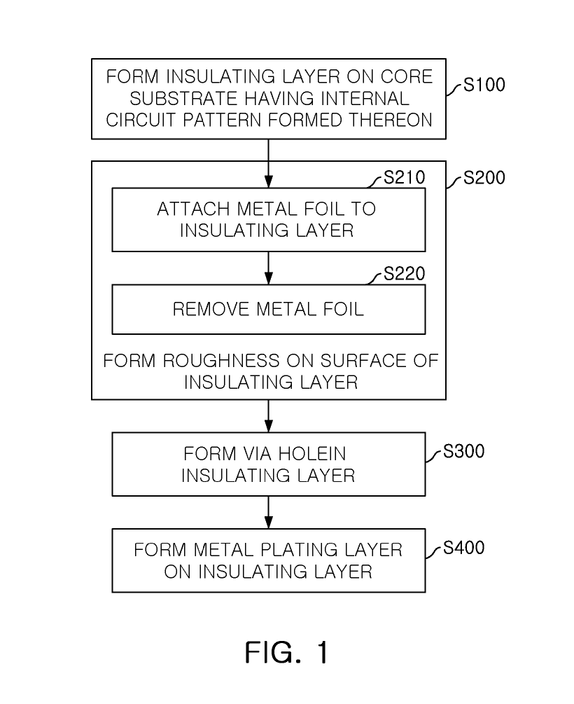

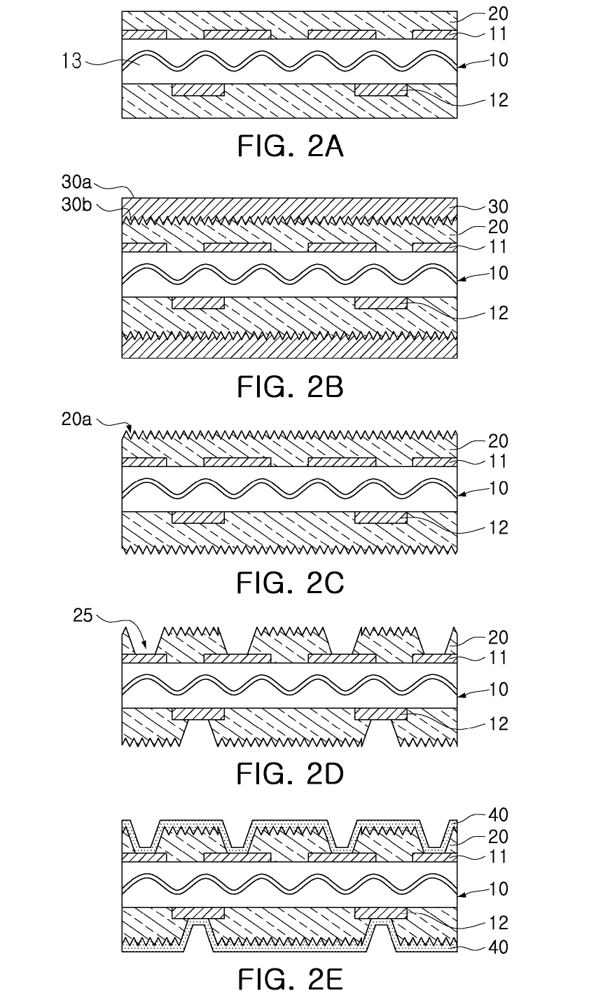

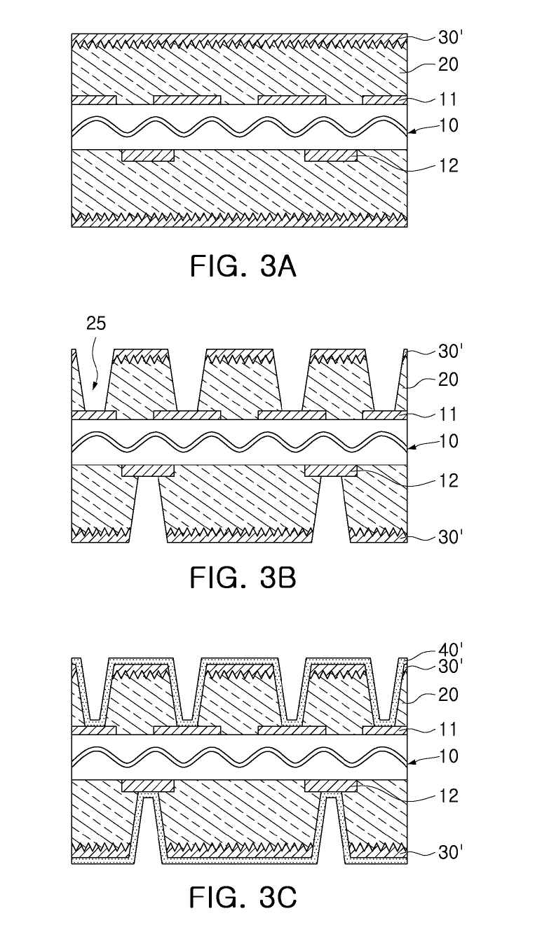

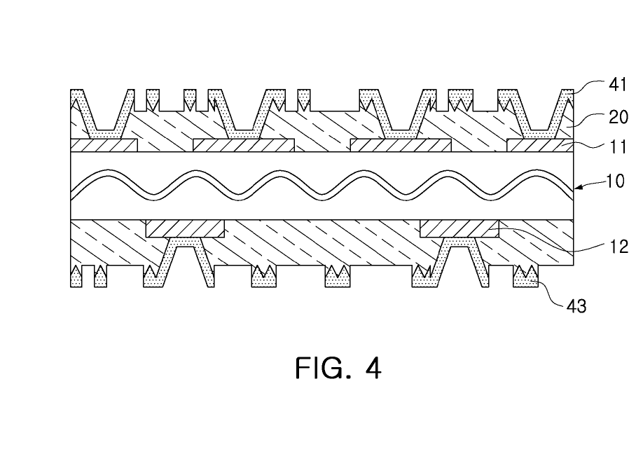

FIG. 1 is a flowchart showing a method of manufacturing a printed circuit board according to an exemplary embodiment of the present invention; FIG. 2 shows a process forming a circuit pattern in a semi additive process (SAP) method according to an exemplary embodiment of the present invention; FIG. 3 shows a process forming a circuit pattern in a modified semi additive process (MSAP) method according to another exemplary embodiment of the present invention; and FIG. 4 is a cross-sectional view showing a printed circuit board having a fine circuit pattern according to an exemplary embodiment of the present invention.

Referring to FIG. 1, a method of manufacturing a printed circuit board according to an exemplary embodiment of the present invention includes: forming an insulating layer on a core substrate having an internal circuit pattern formed therein (S100); forming roughness on a surface of the insulating layer (S200); forming via holes in the insulating layer (S300); and forming a metal plating layer on the insulating layer (S400).

The forming of the roughness on the surface of the insulating layer (S200) may include attaching a metal foil to the insulating layer (S210) and etching and removing the metal foil (S220).

Referring to FIG. 4, a printed circuit board according to an exemplary embodiment of the present invention may include a core substrate 10 on which first circuit patterns 11 and 12 are formed; and insulating layers 20 covering the first circuit patterns 11 and 12 and having uniform surface roughness on a nano scale formed therein, and may further include second circuit patterns 43 formed on the insulating layers 20 by plating. In addition, the printed circuit board may include via patterns 41 electrically connecting the first circuit patterns 11 and 12 to the second circuit patterns 43 and penetrating through the insulating layers 20.

According to the exemplary embodiment of the present invention, the uniform roughness on a nanoscale is formed in the insulating layers 20, such that thin, fine second circuit patterns may be formed on the insulating layers 20.

A method of manufacturing a printed circuit board according to an exemplary embodiment of the present invention will be described with reference to FIG. 2.

The method of manufacturing the printed circuit board according to the exemplary embodiment of the present invention includes: preparing a core substrate 10 on which first circuit patterns 11 and 12 are formed; forming insulating layers 20 on the core substrate 10; forming uniform surface roughness on a nanoscale by attaching metal foils to the insulating layers 20; and forming second circuit patterns 43 and via patterns 41 in the insulating layers 20, the via patterns 41 electrically connecting the first circuit patterns 11 and 12 to the second circuit patterns 43.

Referring to FIG. 2A, the core substrate 10 on which the first circuit patterns 11 and 12 are formed is prepared. The insulating layers 20 are then formed on the core substrate 10 on which the first circuit patterns 11 and 12 are formed.

The core substrate 10 may allow for a layer including a circuit pattern to be additionally built-up on the surface thereof.

According to an exemplary embodiment of the present invention, the core substrate 10, having the first circuit patterns 11 and 12 formed on one surface or both surfaces of an internal substrate 13 thereof, has the insulating layer 20 built-up thereon, and then, the second circuit pattern 43 is built-up on the insulating layer.

According to an exemplary embodiment of the present invention, the internal substrate 13 maybe made of a material, such as prepreg. Prepreg, which may be in a semi-cured state, has good adhesion properties.

In this case, the feature in which a layer is built-up on the core substrate 10 means a state in which multilayer circuit such as a double-layer circuit or the like is organically interconnected and attached to the core substrate 10 so as not to be separated therefrom, that is, a stacked state.

The circuit patterns 11 and 12 are formed on one or both surfaces of the internal substrate 13 to form the core substrate 10 and then, the insulating layer 20 is formed on the core substrate 10 on which the first circuit patterns 11 and 12 are formed. The insulating layer 20 may be made of a resin such as epoxy or polyimide.

Referring to FIGS. 2B and 2C, a metal foil is attached to the insulating layer 20 to form uniform surface roughness on a nanoscale.

According to an exemplary embodiment of the present invention, the metal foil 30 including a rough surface is attached to the insulating layer 20, thereby forming roughness on a surface of the insulating layer. After the roughness formed on the rough surface of the metal foil 30 attached to the surface of the insulating layer is transferred to the insulating layer, the metal foil 30 may be removed.

In other words, referring to FIG. 2B, the metal foil 30 is attached to the insulating layer so as to form appropriate roughness therein. The metal foil 30, configured of a smooth surface 30a and a rough surface 30b, may be formed such that the rough surface 30b of the metal foil 30 is attached to the insulating layer 20.

According to an exemplary embodiment of the present invention, the roughness may be formed on the surface of the insulating layer in a manner that concave and convex roughness portions formed on the rough surface 30b of the metal foil 30 are transferred to the surface of the insulating layer. Therefore, the roughness of the metal foil 30 is appropriately selected, thereby allowing for the control of the magnitude of the roughness formed on the surface 20a of the insulating layer 20.

The roughness formed on the metal foil 30 is uniformly formed over the metal foil 30, such that uniform roughness may be formed over the surface 20a of the insulating layer, different from the related art in which roughness is formed by an etching process.

According to an exemplary embodiment of the present invention, the metal foil may be made of a conductive material forming the circuit pattern. Therefore, a portion of or the entirety of the metal foil may be removed by a removing process such as an etching process, after the roughness is formed. In the case in which the portion thereof is removed, the metal foil may form a portion of the circuit pattern.

According to an exemplary embodiment of the present invention, the metal foil is not specifically limited; however, it may be copper foil. When a copper thin film is formed by removing a portion of the copper foil, the circuit pattern may be formed by a modified semi additive process (MSAP) method and the portion of the copper foil may form a portion of the circuit pattern.

According to an exemplary embodiment of the present invention, arithmetical average roughness (Ra) of the insulating layer 20 may be 300 nm or less, more preferably, from 150 to 250 nm. In other words, roughness in a very fine size may be formed in the surface of the insulating layer 20.

Adhesion with a metal thin film 40 bonded to the insulating layer 20 may be controlled according to the roughness formed in the surface 20a of the insulating layer. When the magnitude of the roughness is too great, the level of the adhesion with the metal thin film 40 is too great, such that overetching should be performed in a subsequent process such as an etching process, which is not appropriate. On the other hand, when the magnitude of the roughness is too low to be smooth, the adhesion with the metal thin film is not sufficient, such that the metal thin film 40 is separated. Therefore, the roughness formed on the surface 20a of the insulating layer may be controlled so as to have an appropriate size. In particular, the surface 20a of the insulating layer may be controlled to have arithmetical average roughness (Ra) of 300 nm or less, preferably, from 150 to 250 nm.

The uniform roughness may not be formed on the surface 20a of the insulating layer by a chemical method of forming roughness; however, the roughness of the surface 20a of the insulating layer may be controlled by selecting the metal foil 30 having a desired magnitude of roughness according to an exemplary embodiment of the present invention.

According to an exemplary embodiment of the present invention, the metal thin film having a fine thin film shape may be formed in the insulating layer 20 by plating.

A predetermined level of adhesion should be secured between the insulating layer and the circuit pattern in order to form the fine circuit pattern on the insulating layer 20. However, according to an exemplary embodiment of the present invention, the uniform fine roughness is formed on the insulating layer 20, such that the metal thin film may be formed by plating, and thus the circuit pattern having a fine size may be formed through a process such as an etching process or the like.

According to an exemplary embodiment of the present invention, the fine circuit pattern maybe formed on the surface 20a of the insulating layer. In other words, the line/space interval of the second circuit pattern 43 and the via pattern 41 may be finely formed. The reason for this is that the metal thin film may be formed on the insulating layer by plating and the thin film formed by the plating method may maintain a predetermined level of adhesion by the uniform roughness formed in the insulating layer.

Therefore, the portion of the metal thin film is removed by the process such as an etching process or the like, such that the circuit pattern having a fine size may be formed.

According to an exemplary embodiment of the present invention, the uniform roughness is provided to provide a predetermined level of adhesion allowing for the attachment with a plating layer, such that the thin film may be formed.

According to an exemplary embodiment of the present invention, the circuit pattern formed by the metal thin film may have a thickness of 25 μm or less and the roughness having a fine magnitude may also be formed, such that a thickness of the insulating layer may also be reduced to 100 μm or less.

Meanwhile, when the magnitude of the roughness is too great, overetching should be performed, such that the fine circuit pattern cannot be formed. When the magnitude of the roughness is too low, the circuit pattern may be peeled off. Therefore, the surface of the insulating layer should be formed to have roughness of a fine magnitude so as to have appropriate adhesion.

According to an exemplary embodiment of the present invention, the surface 20a of the insulating layer is formed to have an appropriate roughness, such that the second circuit pattern 43 having line/space (L/S) interval in a fine size may be formed, and in particular, the second circuit pattern 43 may be formed to have the line/space (L/S) interval of 10 μm/10 μm or less.

Meanwhile, in a general printed circuit board, in order to forma circuit pattern, after copper foil, a metal thin film, is attached onto a core substrate on which an insulating layer is formed, a resist is printed onto a circuit wire, which is to be continuously maintained as copper foil, and the printed board is put into an etchant in which copper maybe melted. Then, portions of the board not covered with the resist are corroded, and thus, if the resist is removed thereafter, the copper foil is maintained to have a desired shape, thereby forming a circuit pattern.

According to an exemplary embodiment of the present invention, the circuit pattern maybe formed by a semi additive process (SAP) method or a modified semi additive process (MSAP) method. In the SAP method, a dry film resist (DFR) is attached to the board and is subjected to printing, exposing, and developing, to form pattern walls. Then, copper plating is performed between the pattern walls by an electroless plating method or an electrolyte plating method. Thereafter, if the circuit pattern is full-etched by a thickness of copper in a state in which the pattern walls formed of the DFR is removed, only copper foil circuit pattern is maintained on the surface thereof. In the SAP method, the copper plating maybe performed by an electroless plating method or an electrolyte plating method.

Meanwhile, in the MSAP method, a circuit pattern may be formed by performing copper plating in a state in which copper foil is formed on an insulating layer by an electroless plating method or an electrolyte plating method, in the same manner as the SAP method.

According to an exemplary embodiment of the present invention, when performing plating for forming a circuit pattern on an insulating layer, the roughness is formed on the surface of the insulating layer to provide uniform adhesion between the insulating layer and the metal thin film, such that a very thin metal thin film may be formed.

Referring to FIG. 2C, after the roughness is formed on the insulating layer 20 on which the metal foil 30 is formed, the metal foil 30 is subjected to a removing process. The metal foil 30 may be removed by an etching process. In addition, the metal foil may be subjected to a full-etching process or a semi-etching process.

When the metal foil is full-etched as shown in FIGS. 2C to 2E, a circuit pattern may be formed by being subjected to the semi additive process (SAP), through electroless plating, electrolyte plating, and etching.

When the metal foil is semi-etched to partially remove the metal foil 30 formed on the surface of the insulating layer 20 as shown in FIGS. 3A to 3C, a thin film layer 30′ maybe formed on the insulating layer 20. Then, a circuit pattern in an appropriate form may be formed on the insulating layer by being subjected to the modified semi additive process (MSAP), that is, through electroless plating and electrolyte plating using copper foil as a seed layer, and etching.

Referring to FIG. 2C in which the metal foil is full-etched and FIG. 3A in which the metal foil is semi-etched, the metal foil is full-etched or semi-etched, the metal foil 30 formed to be thick on the surface of the insulating layer maybe removed by full-etching or semi-etching. The metal foil is very thick while in a foil state, such that the thin film layer 30′ formed to be extremely thin should be formed on the insulating layer 20 in order to form a thin circuit pattern.

Therefore, in the exemplary embodiment of the present invention, the metal foil is removed by full-etching (FIG. 2C) or semi-etching (FIG. 3A) the metal foil formed on the insulating layer 20.

Referring to FIGS. 2D and 3B, holes 25 are formed in the insulating layer 20 by laser drilling or computer numerical control (CNC) drilling.

The holes 25 may expose the first circuit patterns 11 and 12 and may be provided as through holes used in electrically connecting the second circuit patterns 43 to be formed later to the first circuit patterns 11 and 12.

Referring to FIGS. 2E and 3C, metal plating layers 40 and 40′ are formed on the insulating layer 20 and/or the thin film layer 30′ formed on the insulating layer 20. The metal plating layers 40 and 40′ are not limited thereto; however, the metal plating layers 40 and 40′ may be formed by forming a thin seed layer (not shown) by a vacuum deposition method and then adding a metal layer thereon by electrolyte plating or electroless plating.

According to an exemplary embodiment of the present invention, the metal plating layer maybe a copper plating layer made of copper; however, it is not limited thereto and the metal plating layer may be made of a conductive metal. The metal plating layer may be formed to have a thickness of 0.5 μm, preferably, a thickness of 10 nm to 0.5 μm.

Referring to FIG. 4, portions of the metal plating layer (see FIG. 2C) or portions of the metal plating layer 40′ and the thin film layer 30′ are etched and removed in order to form the second circuit pattern 43 in a desired shape. Therefore, portions of the insulating layer 20 are exposed, such that the second circuit patterns 43 and the via patterns 41 connecting the second circuit patterns 43 are formed on the insulating layer 20.

According to an exemplary embodiment of the present invention, the surface roughness is formed by using a rough surface of the metal foil, such that a separate wet process, such as a desmear process, is not introduced so as to avoid creating waste liquid, thereby rendering the present invention environment-friendly.

In the case of a chemical process such as the desmear process, the metal foil is attached and etched to be partially or entirely removed, without being subjected to a complicated process such as a swelling process, an etching process, and a reduction process, such that the time required for the process may be reduced and thus the manufacturing costs and manufacturing time thereof may be reduced.

According to an exemplary embodiment of the present invention, in order to form roughness of a desired magnitude in the insulating layer, the metal foil having a desired magnitude of roughness is attached to the insulating layer, such that the roughness of the metal foil may be transferred to the insulating layer. In other words, in order to form roughness of a desired magnitude on the insulating layer, the metal foil having a desired magnitude of roughness maybe appropriately selected. Therefore, the magnitude of roughness may be finely controlled to have a desired magnitude.

According to an exemplary embodiment of the present invention, roughness of a fine magnitude is formed, such that adhesion is maintained between the conductive layer and the insulating layer, even in the case that a pattern having a fine size is formed on the insulating layer. Therefore, fineness may be implemented in the circuit pattern, such that the product may be compact.

In addition, in the case of the metal foil, a uniform roughness is formed over the surface thereof, such that a uniform roughness may be formed over the surface of the insulating layer, without being subjected to a chemical roughness forming process, and thus, the reliability of a product may be enhanced.

As set forth above, according to exemplary embodiments of the present invention, there are provided a printed circuit board having a fine circuit pattern by forming a uniform roughness on an insulating layer and securing adhesion between a conductive layer and the insulating layer, and a method of manufacturing the same.

While the present invention has been shown and described in connection with the exemplary embodiments, it will be apparent to those skilled in the art that modifications and variations can be made without departing from the spirit and scope of the invention as defined by the appended claims.

What is claimed is:

1. A printed circuit board comprising:
a core substrate having a first circuit pattern formed thereon; and
an insulating layer formed on the core substrate and having a uniform surface roughness on a nano scale formed thereon.

2. The printed circuit board of claim 1, further comprising a second circuit pattern formed on the insulating layer having the roughness formed thereon by plating.

3. The printed circuit board of claim 2, further comprising a via pattern electrically connecting the first circuit pattern to the second circuit pattern and penetrating through the insulating layer.

4. The printed circuit board of claim 1, wherein the insulating layer has an arithmetical average roughness (Ra) of 300 nm or less.

5. The printed circuit board of claim 4, wherein the arithmetical average roughness (Ra) ranges from 150 to 250 nm.

6. The printed circuit board of claim 2, wherein the second circuit pattern has a line/space interval of 10 μm/10 μm or less.

7. The printed circuit board of claim 2, wherein the second circuit pattern has a thickness of 25 μm or less.

8. The printed circuit board of claim 1, wherein the insulating layer has a thickness of 100 μm or less.

9. A method of manufacturing a printed circuit board, the method comprising:
preparing a core substrate having a first circuit pattern formed thereon;
forming an insulating layer on the core substrate;
transferring a surface roughness of a metal foil to the insulating layer and forming a uniform surface roughness thereon; and
forming a second circuit pattern and a via pattern electrically connecting the first circuit pattern to the second circuit pattern on the insulating layer.

10. The method of claim 9, wherein the second circuit pattern and the via pattern are formed by plating.

11. The method of claim 9, wherein the metal foil is copper foil.

12. The method of claim 9, wherein the forming of the roughness includes:
attaching the metal foil to the insulating layer; and
removing the metal foil.

13. The method of claim 12, wherein the removing of the metal foil is performed by full-etching or semi-etching of the metal foil.

14. The method of claim 12, wherein the forming of the second circuit pattern and the via pattern is performed by a semi additive process (SAP) method or a modified semi additive process (MSAP) method.

15. The method of claim 9, wherein the insulating layer has an arithmetical average roughness (Ra) of 300 nm or less.

16. The method of claim 15, wherein the arithmetical average roughness (Ra) ranges from 150 to 250 nm.

17. The method of claim 9, wherein the second circuit pattern has a line/space interval of 10 μm/10 μm or less.

18. The method of claim 9, wherein the second circuit pattern has a thickness of 25 μm or less.

19. The method of claim 9, wherein the insulating layer has a thickness of 100 μm or less.
